(19) United States
(12) Patent Application Publication
(10) Pub. No.: US 2007/0052048 A1
(43) Pub. Date: Mar. 8, 2007

(54) Strain compensated high electron mobility transistor

(75) Inventor: William E. Hoke, Wayland, MA (US)

Correspondence Address: RAYTHEON COMPANY;c/o DALY, CROWLEY, MOFFORD & DURKEE, LLP, 354A TURNPIKE STREET, SUITE 301A, CANTON, MA, 02021-2714, US

(73) Assignee: Raytheon Company

(21) Appl. No.: 11/221,444

(22) Filed: Sep. 8, 2005

(51) Int. Cl. H01L 27/14

(52) U.S. Cl. 257/431; 257/E31.019

(57) ABSTRACT

A semiconductor structure having a III-V substrate; a first III-V donor layer having a relatively wide bandgap disposed over the substrate; a III-V channel layer having a relatively narrow bandgap disposed on the donor layer; a second III-V donor layer disposed on the channel layer having a relatively wide bandgap. The first III-V donor provides both tensile strain to compensate compressive strain in the channel layer and carriers to the channel layer.

### TECHNICAL FIELD

This invention relates generally to high electron mobility transistors (HEMTs) and more particularly to HEMTs having strain compensation.

### BACKGROUND AND SUMMARY

As is known in the art, there are several types of field effect transistors (FETs) generally used at microwave and millimeter wave frequencies. These FETs include metal semiconductor field effect transistors (MESFETs) and high electron mobility transistors (HEMTs), each fabricated from Group III-V materials. What distinguishes a HEMT from a MESFET is that in a HEMT charge is transferred from a doped charge donor layer to an undoped channel layer. The interface between the donor barrier layer and the channel layer is called a heterojunction. At the heterojunction, the conduction band is at a higher energy in the donor barrier layer than in the channel layer. This conduction band discontinuity results in electrons leaving the donor barrier layer and entering the channel layer. In most heterojunction, but not all, the donor barrier layer has a larger bandgap than the channel layer.

There are generally two types of high electron mobility transistors. One type is referred to simply as a HEMT whereas the other type is a pseudomorphic HEMT. The difference between the HEMT and the pseudomorphic HEMT is that in the pseudomorphic HEMT, the channel layer incorporated into the device has a lattice constant which differs significantly from the lattice constants of other materials of the device. Thus due to resulting lattice constant mismatch the crystal structure of the material forming the channel layer is strained. Furthermore, the stain in the channel layer is elastic without the formation of dislocations or other crystalline defects. In a HEMT structure, charge is transferred from the donor layer to an undoped channel layer. For Group III-V materials, the doped charge donor layer is comprised of a wide-band gap material such as gallium aluminum arsenide, whereas the channel layer is typically comprised of a lower bandgap material, such as gallium arsenide or indium gallium arsenide. A HEMT including an active region of AlGaAs and GaAs is unstrained, AlAs has a lattice constant α=5.6605 Angstroms, whereas gallium arsenide has a lattice constant α=5.6533 Angstroms. Since these lattice constants are similar, the channel layer is unstrained.

In the pseudomorphic HEMT, the undoped gallium arsenide channel layer is replaced by a channel layer comprised of a lower bandgap material, such as gallium indium arsenide. Indium arsenide has a lattice constant α=6.0584. Since indium arsenide has a substantially different lattice constant compared to either gallium arsenide or aluminum arsenide, indium incorporation provides a crystal having a lattice constant which is substantially larger than the lattice constant of gallium arsenide or gallium aluminum arsenide. This lattice mismatch makes practical growth of such devices difficult and otherwise limits several advantages which would accrue to a device using GaInAs as the channel layer. For example, the use of gallium indium arsenide in a HEMT provides several performance advantages over gallium arsenide. Since gallium indium arsenide has a smaller bandgap than gallium arsenide, the conduction band discontinuity at the gallium aluminum arsenide/gallium indium arsenide heterojunction is increased thereby increasing the charge density transferred into the channel layer. Moreover, gallium indium arsenide also has a higher electron mobility and higher electron saturated velocity than gallium arsenide. Each of these benefits thus provides a pseudomorphic HEMT which can handle higher power levels, as well as, operate at higher frequencies with improved noise properties than a HEMT using gallium arsenide as the channel layer. Moreover, these benefits increase with increasing indium concentration (X) in the Ga₁₋ₓInₓ As layer.

Accordingly, a major objective in fabricating a high performance pseudomorphic HEMT structure is to maximize the amount of indium contained in the gallium indium arsenide layer. A problem arises, however, in increasing indium concentration. As mentioned above, gallium indium arsenide has a lattice constant which is larger than gallium arsenide or gallium aluminum arsenide, with the latter having substantially equal lattice constants. This disparity in lattice constants increases with increasing indium concentration. Thus, when gallium indium arsenide is disposed over the gallium arsenide, the film develops intrinsic stresses which induce a very high compressive strain in the gallium indium arsenide. For a gallium indium arsenide layer which is thicker than the so-called “critical thickness” of the GaInAs layer on gallium arsenide or gallium aluminum arsenide, this intrinsic strain causes the gallium indium arsenide film to be disrupted with formation of various types of crystal dislocations or defects. The presence of such crystal dislocations seriously degrades the electron transport properties of the GaInAs layer. For a gallium indium arsenide layer having a thicknesses less than the so-called critical thickness of the layer, the material is elastically strained without these dislocations forming. In the growth plane, the GaInAs layer takes on the lattice constant of the underlying gallium arsenide or gallium aluminum arsenide layer, whereas the crystal of the GaInAs is deformed such that in a plane perpendicular to the growth plane the crystal is expanded. This type of layer is termed “pseudomorphic” from which is developed the term pseudomorphic HEMT. With increasing indium concentration, the critical thicknesses at which the GaInAs layer forms crystal defects decreases. For example, for a channel layer comprised of gallium indium arsenide having the concentration Ga_{0.8}In₂ As a layer thickness of approximately 100 Angstroms is the maximum thickness. Layers thinner than approximately 70 Angstroms are not attractive due to the increased importance of the quantum size effect which reduces the effective conduction band discontinuity. Thicknesses much above 100 Angstroms result in the above-mentioned lattice dislocation problem.

An example of a PHEMT structure is shown in FIG. 1. A key layer in the structure is the channel layer 28. In a pseudomorphic HEMT, the channel layer would be InGaAs which has a smaller bandgap than GaAs which, in turn, is smaller than AlGaAs. The charge donor layer 30, often AlGaAs, has a conduction band energy greater than the channel layer. The barrier layer is also a charge donor layer containing silicon dopant atoms. (FIG. 1 shows pulse doping but uniform doping can be used as well.) Electrons donated by the silicon atoms in the barrier fall into the channel layer well. This separation of the electrons from the donating silicon atoms increases the electron mobility and saturated velocity. Furthermore InGaAs has a higher mobility and peak saturated velocity than either GaAs or AlGaAs enhancing microwave and millimeter-wave operation.

As described in my U.S. Pat. No. 5,060,030 entitled Psudomorphic HEMT Having Strained Compensation Layer” issued Oct. 22, 1991 and assigned to the same assignee as the present invention, a high electron mobility transistor is described having a substrate for supporting a semiconductor active region. The semiconductor active region includes a channel layer and a charge donor layer. The channel layer is comprised of a narrow bandgap Group III-V material having an element which causes said material to have a lattice mismatch to that of the substrate. The narrow bandgap material, when disposed over said substrate develops an intrinsic lattice strain. The charge donor layer is comprised of a wide bandgap Group III-V material and is arranged to donate charge to said channel layer. The HEMT further includes a strain compensation layer having an intrinsic lattice strain opposite to that of the channel layer which is disposed between said channel layer and substrate. With this particular arrangement, the critical thickness of the channel layer of a pseudomorphic HEMT may be increased or alternatively the concentration of the element causing the strain of the material of the channel layer may be increased. Either advantage would significantly improve device performance characteristics. The strain compensating layer has a strain characteristic which is opposite in magnitude to the strain characteristic of the channel layer. The composite layer provided has a pair of lattice strains which compensate one another. Since strains are compensated, either the thickness, the concentration of the straining element in the channel layer, or both may be increased over that obtained without the strain compensating layer. More particularly, the channel layer develops an intrinsic lattice compressive strain and a charge donor layer comprised of a wide bandgap Group III-V material, said layer being arranged to donate charge to said channel layer. The strain compensation layer has an intrinsic lattice tensile strain disposed between said channel layer and said substrate. With this particular arrangement, the critical thickness of the channel layer of a pseudomorphic HEMT may be increased or alternatively the concentration of indium could be increased. Either advantage will significantly improve device performance characteristics. The strain compensating layer has a tensile strain characteristic which is opposite in magnitude to the compressive strain characteristic of the indium gallium arsenide layer, whereas the composite layer provided has a pair of lattice strains which compensate one another. Since strains are compensated, this permits either the thickness or alternatively the indium concentration in the gallium indium arsenide layer to be increased over that obtained without the strain compensating layer. While my U.S. Pat. No. 5,060,030 describes a single pulse doped structure a double pulse doped structure is practical as described in my paper entitled “High performance double pulse doped pseudomorphic AlGaAs/InGaAs transistors grown by molecular-beam epitaxy” published in the J. Vac. Sci. Technol. B 10, 1066, 1992, the entire subject matter thereof being incorporated herein by reference.

I have now recognized that the strain compensating layer of the HEMT described in my U.S. Pat. No. 5,060,030 may be further improved. More particularly, I now recognize that the strain compensating layer provides only the function of strain compensation. Consequently there is only one charge donor layer which is above the channel and different than the strain compensating layer. In the accordance with my present invention, a new strain compensation layer provides both strain compensation and serves as a charge donor layer. Therefore charge is provided to the channel from the strain compensating layer. With my present invention, there are two new types of structures to provide charge to the channel: (1) the structure where charge is provided from above and below (strain compensating layer) the channel, and (2) the structure where charge is provided just from below the channel from the strain compensating donor layer.

Thus, in accordance with the invention, a semiconductor structure is provided having a III-V substrate; a first III-V donor layer having a relatively wide bandgap disposed over the substrate; a III-V channel layer having a relatively narrow bandgap disposed on the donor layer; a second III-V donor layer disposed on the channel layer having a relatively wide bandgap. The first III-V donor provides both tensile strain to compensate compressive strain in the channel layer and carriers to the channel layer.

The details of one or more embodiments of the invention are set forth in the accompanying drawings and the description below. Other features, objects, and advantages of the invention will be apparent from the description and drawings, and from the claims.

### DESCRIPTION OF DRAWINGS

FIG. 1 is a diagrammatical sketch of a semiconductor structure according to the PRIOR ART; and

FIG. 2 is a diagrammatical sketch of a semiconductor structure according to the invention.

Like reference symbols in the various drawings indicate like elements.

### DETAILED DESCRIPTION

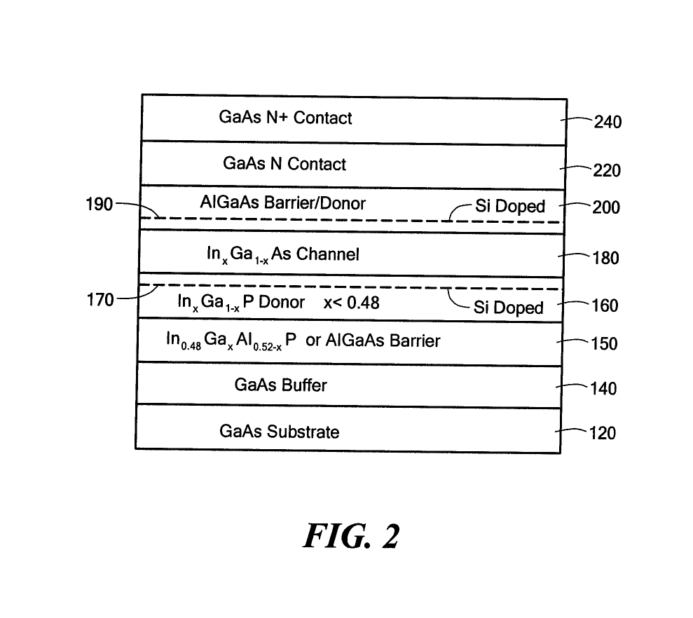

Referring now to FIG. 2, a semiconductor structure 100 is shown having: a III-V substrate 120, here GaAs; a buffer layer 140, here GaAs on the substrate 120; barrier layer 150, lattice matched to the GaAs buffer layer 140 and substrate 120, here, for example, In_{0.48}GaₓAl_{0.52-x}P, and/or AlGaAs; a first III-V donor layer 160, here shown as InₓGa₁₋ₓP with x less than 0.48, and having a relatively wide bandgap disposed on the buffer layer 140; a III-V channel layer 180, here InₓGa₁₋ₓAs, where 0<X<0.40 disposed on the first donor layer 160, having a relatively narrow bandgap; a second III-V donor layer 200, here shown as AlGaAs, disposed on the channel layer 180. The donor layers have relatively large bandgaps such that the conduction band energy is greater in the donor layers than in the channel layer resulting in charge transfer from the donor layers to the channel layer. The first III-V donor layer 160 provides both tensile strain to compensate compressive strain in the channel layer 180 and charge carriers to the channel layer 180.

The structure 100 is a HEMT structure with thin silicon doped layers 170 and 190 to provide, here, a double-pulsed doped structure as described in my above referenced paper.

Disposed on the second donor layer 200 is a GaAs N doped ohmic contact layer 220. Disposed on the GaAs layer 220 is a N+ doped GaAs ohmic contact layer 240 for source and drain electrode contacts, not shown, when the structure is used to form a FET. In such case a double recess is formed through the contact layers 240 and 220 and into the donor layer 200, as described in my above-referenced article.

Properties required for the strain compensating-first donor layer 160 are:

1. The lattice constant is less than the GaAs substrate 120 so that tensile strain is provided to compensate the compressive strain in the InGaAs channel layer 180.

2. The thickness of the strain compensating layer is less than the critical thickness so that the layer is fully elastically strained with no stain-relaxing dislocations.

3. A III-V material like GaAs so that there is no cross contamination between the strain compensating layer, i.e., layer 160, and surrounding layers.

4. A large bandgap such that the conduction band energy is greater than the conduction band energy in the channel layer so dopant atoms such as silicon will provide carriers (either electrons or holes) to the channel layer 180. The size of the bandgap of the stain compensating donor layer 160 should be greater than 1.7 eV, such as, for example InₓGa₁₋ₓP with X<0.48; with a lattice constant smaller than GaAs and the bandgap is 1.90 eV or greater; quaternary In_{0.48-x}(Ga_{y}Al_{1-y})_{0.52+x}P (obtained by adding aluminum and reducing gallium which further increases the bandgap); GaAsₓP₁₋ₓ with X<0.4 since the lattice constant will be less than GaAs and the bandgap is greater than 1.7 eV; quaternary Al_{y}Ga_{1-y}AsₓP₁₋ₓ.

Thus, the donor layer 160 should have a conduction band energy greater than the conduction band energy of the channel layer. In absence of this knowledge, a bandgap greater than 1.7 eV is preferred.

More particularly, increasing the indium concentration in the InGaAs channel layer 180 deepens the well to increase the electronic charge transfer for increased FET device current. Also higher indium contents further increases the electron mobility and peak saturated velocity for high frequency operation. Alloying indium into GaAs, however, results in compressive strain due to the larger atomic size of indium compared to gallium or aluminum. When the strain becomes too great for a given thickness, known as the critical thickness, the strain is relieved by device-degrading dislocations. Consequently the strain in the InGaAs layer 180 must, absent layer 160, be backed off from this critical strain so that the strained InGaAs layer 180 is elastically deformed or pseudomorphic. From my experience in manufacturing PHEMTs, a benchmark for a satisfactory amount of elastic strain content is the strain in a 100 Å In_{0.20}Ga_{0.80}As layer. This strain is determined by the layer thickness and indium content which determines the lattice mismatch between InGaAs and GaAs. The lattice mismatch is given by:
Mismatch=[(In_{0.20}Ga_{0.80}As LC)−(GaAs LC)]/(GaAs LC)=0.0143 (1)
where LC stands for lattice constant. Entering the lattice constant values in Equation 1 determines a satisfactory amount of elastic strain, Sₘ, for manufactured PHEMTs as:
Sₘ=0.0143×100 Å (2)
It should be noted that Equation 2 is satisfied for various products of InGaAs compositions and thicknesses. Thus a 140 Å In_{0.14}Ga_{0.86}As layer also has a strain of Sₘ. Using very thin (less than approximately 75 Å) InGaAs layers, however, is deleterious since the depth of the InGaAs well is reduced due to the quantum size effect.

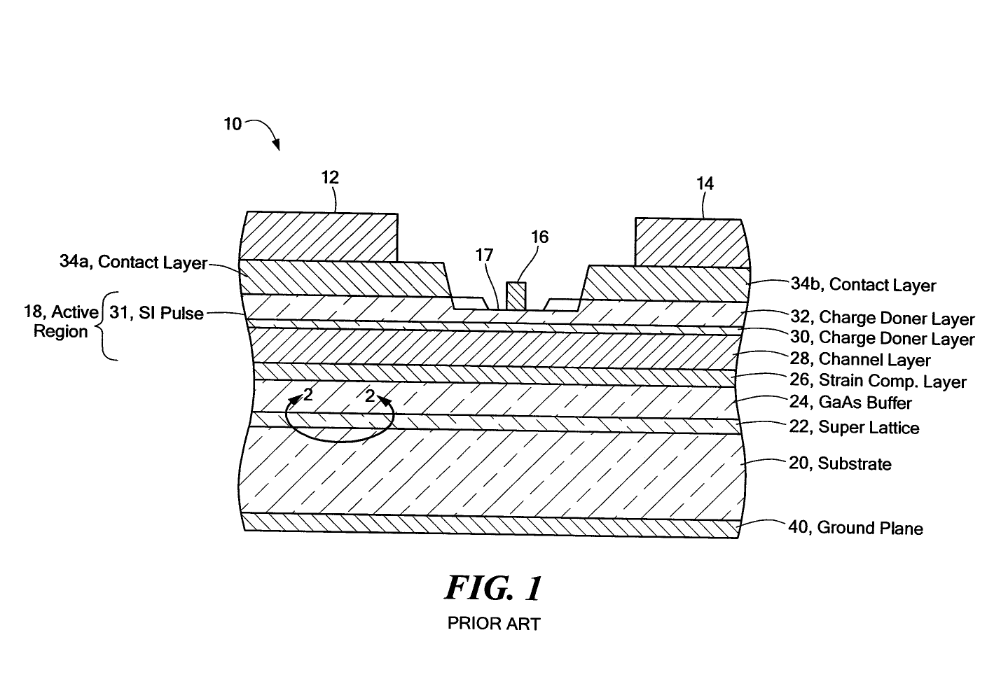

In considering changes to the structure in FIG. 1 to permit more elastic strain in the InGaAs channel layer, an important consideration is that a complex manufacturing process has been established. In particular a selective first recess etch is used to etch through the GaAs top layers and stop on the AlGaAs barrier layer. A second etch is used to etch into the AlGaAs barrier layer to form a narrow, second recess for the FET. Using photolithographic steps, metal is then evaporated into the second recess to form the critical gate electrode for the FET. Furthermore ohmic contacts are also formed on the surface. i.e., on layer 240. It would be advantageous that any changes to the structure of FIG. 1 do not alter the layers above the InGaAs channel layer so that the established gate and ohmic processes are maintained.

Thus, with my present invention, I have incorporated an elastically (pseudomorphically) strained InGaP donor-barrier layer 160 underneath the InGaAs channel layer 180 which has a tensile strain≦Sₘ. The tensile strain compensates compressive strain in the InGaAs channel layer 180. Consequently the compressive strain in the InGaAs layer 180 can be increased up to 2Sₘ since the overall layer structure 100 will have a total strain of 2Sₘ−Sₘ=Sₘ and be stable. When properly grown, a PHEMT structure 100 containing a 100 Å In_{0.40}Ga_{0.60}As layer 180 with an underlying tensile strained InGaP layer 160 will exhibit overall layer stability.

FIG. 2 labels this layer as the donor layer and the underlying layer as the barrier layer. The InGaP layer does act as part of the barrier. Since it is strained, it cannot be made arbitrarily thick. This is why a lattice matched barrier layer is included below the strain compensating layer. Underneath the strained InGaP donor layer 160 is the barrier layer 150 which can be either lattice matched InGaP, lattice matched InGaAlP, and/or AlGaAs. This barrier layer 150 is desirable to insure that charge transfer does not occur from the donor InGaP layer 160 to the underlying GaAs buffer layer 140 which has a smaller bandgap than the donor layer 160.

It should be noted that the mechanism of strain compensation can also be achieved by replacing some of the gallium in the tensile strained InGaP layer 160 with aluminum to form the quaternary material In_{0.48-x}(Ga_{y}Al_{1-y})_{0.52+x}P. Adding aluminum will further increase the bandgap and conduction band discontinuity.

The invention has the following beneficial properties:

1. The elastic strain in the InGaAs channel layer 180 can be increased up to a factor of 2 enabling higher indium contents and/or thicker layers. Tensile strained InₓGa₁₋ₓP with X<0.48, layer 160, is a good donor material.

2. Lattice matched In_{0.48}Ga_{0.52}P has a bandgap of 1.9 eV which is larger than the bandgap (approximately 1.75 eV) of the AlGaAs donor-barrier layers with approximate composition of Al_{0.25}Ga_{0.75}As used in the PHEMT structure of FIG. 1. By changing the composition of the InGaP so that the layer 160 is tensile strained, the indium concentration is reduced which further increases the bandgap and makes the material a very good donor layer. For example, a 140 Å In_{0.35}Ga_{0.65}P layer has a strain of Sₘ and a bandgap of 2.03 eV.

3. Tensile strained InGaP layer 160 is a satisfactory electron donor material. Charge transfer is determined by the conduction band discontinuity between the donor layer 160 and channel layer 180. Charge transfer has been demonstrated between lattice matched In_{0.48}Ga_{0.52}P layer 160 and InGaAs layer 180 but it is smaller than the charge transfer between AlGaAs and InGaAs due to a smaller conduction band discontinuity. By using InGaP compositions that are tensile strained, the bandgap and consequently conduction band discontinuity between InGaP layer 180 and InGaAs layer 160 is further increased.

4. InGaP, AlGaInP, GaAsP, AlGaAsP, GaAs, AlGaAs, and InGaAs are all column III-V materials. Inserting InGaP, AlGaInP, GaAsP, or AlGaAsP into the PHEMT structure will not cause unwanted cross doping of layers.

5. The tensile strained InGaP layer 160 is incorporated into the PHEMT structure underneath the channel layer 180. Therefore the manufacturing processes of Schottky gate and ohmic contact formation are not affected.

With such an arrangement, the properties preferred for a strain compensating donor layer are:

1. The lattice constant is less than the GaAs substrate so that tensile strain is provided to compensate the compressive strain in the InGaAs channel layer 180.

2. A III-V material like GaAs so that there is no cross contamination between the strain compensating layer 160 and surrounding layers.

3. A large bandgap with conduction band energy greater than the conduction band energy of the channel layer so dopant atoms such as silicon will provide carriers (either electrons or holes) to the channel layer 180. The size of the bandgap of the strain compensating donor layer 160 should be greater than 1.7 eV.

Donor layer 160 may be:

1. InₓGa₁₋ₓP with X<0.48, since the lattice constant is smaller than GaAs and the bandgap is 1.90 eV or greater;

2. The quaternary In_{0.48-x}(Ga_{y}Al_{1-y})_{0.52+x}P (obtained by adding aluminum and reducing gallium in InGaP which further increases the bandgap);

3. GaAsₓP₁₋ₓ with X<0.4 since the lattice constant will be less than GaAs and the bandgap is greater than 1.7 eV;

4. The quaternary Al_{y}Ga_{1-y}AsₓP₁₋ₓ with X<0.4;

A number of embodiments of the invention have been described. Nevertheless, it will be understood that various modifications may be made without departing from the spirit and scope of the invention. Accordingly, other embodiments are within the scope of the following claims.

What is claimed is:

1. A semiconductor structure, comprising:
a III-V substrate;
a III-V donor layer disposed over the substrate having a relatively wide bandgap;
a III-V channel layer disposed on the donor layer, such channel layer having a relatively narrow bandgap; and
wherein the III-V donor provides both tensile strain to compensate compressive strain in the channel layer and carriers to the channel layer.

2. The structure recited in claim 1 wherein the bandgap of the donor layer is greater than 1.7 eV.

3. The structure recited in claim 1 wherein the donor layer is InGaP.

4. The structure recited in claim 2 wherein the donor layer is InₓGa₁₋ₓP where X is less than 0.48

5. The structure recited in claim 1 wherein the donor layer is quaternary AlInGaP.

6. The structure recited in claim 2 wherein the donor layer is quaternary In_{0.48-x}(Ga_{y}Al_{1-y})_{0.52+x}P where x is less than 0.48 and y is between 0 and 1.

7. The structure recited in claim 1 wherein the donor layer is GaAsP.

8. The structure recited in claim 2 wherein the donor layer is GaAsₓP₁₋ₓ with X less than 0.4.

9. The structure recited in claim 2 wherein the donor layer is quaternary Al_{y}Ga_{1-y}AsₓP₁₋ₓ where x is less than 0.4 and y is between 0 and 1.

10. The structure recited in claim 1 wherein the channel layer is InGaAs.

11. The structure recited in claim 10 wherein the donor layer has a bandgap greater than 1.7 eV.

12. The structure recited in claim 10 wherein the donor layer is InGaP.

13. The structure recited in claim 11 wherein the donor layer is InₓGa₁₋ₓP where x is less than 0.48

14. The structure recited in claim 10 wherein the donor layer is quaternary AlInGaP.

15. The structure recited in claim 11 wherein the donor layer is quaternary In_{0.48-x}(Ga_{y}Al_{1-y})_{0.52+x}P where x is less than 0.48 and y is between 0 and 1.

16. The structure recited in claim 10 wherein the donor layer is GaAsP.

17. The structure recited in claim 11 wherein the donor layer is GaAsₓP₁₋ₓ with X less than 0.4.

18. The structure recited in claim 11 wherein the donor layer is quaternary Al_{y}Ga_{1-y}AsₓP₁₋ₓ where y is between 0 and 1 and x is less than 0.4.

19. A semiconductor structure, comprising:
a III-V substrate;
a first III-V donor layer disposed over the substrate, the first donor layer having a relatively wide bandgap;
a III-V channel layer disposed on the first donor layer, such channel layer having a relatively narrow bandgap;
a second III-V donor layer disposed on the channel layer having a relatively wide bandgap; and
wherein:
the first III-V donor provides both tensile strain to compensate compressive strain in the channel layer and carriers to the channel layer.

20. The structure recited in claim 19 wherein the bandgap of the first donor layer is greater than 1.7 eV.

21. The structure recited in claim 19 wherein the first donor layer is InGaP.

22. The structure recited in claim 20 wherein the first donor layer is InₓGa₁₋ₓ P where X is less than 0.48.

23. The structure recited in claim 19 wherein the first donor layer is quaternary AlInGaP.

24. The structure recited in claim 20 wherein the first donor layer is quaternary In_{0.48-x}(Ga_{y}Al_{1-y})_{0.52+x}P where X is less than 0.48 and Y is between 0 and 1.

25. The structure recited in claim 19 wherein the first donor layer is GaAsP.

26. The structure recited in claim 20 wherein the first donor layer is GaAsₓP₁₋ₓ with X less than 0.4.

27. The structure recited in claim 20 wherein the first donor layer is quaternary Al_{y}Ga_{1-y}AsₓP₁₋ₓ where X is less than 0.4 and Y is between 0 and 1.

28. The structure recited in claim 19 wherein the channel layer is InGaAs.

29. The structure recited in claim 28 wherein the first donor layer has a bandgap greater than 1.7 eV.

30. The structure recited in claim 28 wherein the first donor layer is InGaP.

31. The structure recited in claim 29 wherein the first donor layer is InₓGa₁₋ₓP where X is less than 0.48.

32. The structure recited in claim 28 wherein the first donor layer is quaternary AlInGaP.

33. The structure recited in claim 29 wherein the first donor layer is quaternary In_{0.48-x}(Ga_{y}Al_{1-y})_{0.52+x}P where X is less than 0.48 and Y is between 0 and 1.

34. The structure recited in claim 28 wherein the first donor layer is GaAsP.

35. The structure recited in claim 29 wherein the first donor layer is GaAsₓP₁₋ₓ with X less than 0.4.

36. The structure recited in claim 29 wherein the first donor layer is quaternary Al_{y}Ga_{1-y}AsₓP₁₋ₓ where Y is between 0 and 1 and X is less than 0.4.
